(19) United States
(12) Patent Application Publication
(10) Pub. No.: US 2017/0278990 A1
(43) Pub. Date: Sep. 28, 2017

(54) APPROACHES FOR SOLAR CELL MARKING AND TRACKING

(71) Applicants: David Aitan Soltz, San Jose, CA (US); Seung Bum Rim, Pleasanton, CA (US)

(72) Inventors: David Aitan Soltz, San Jose, CA (US); Seung Bum Rim, Pleasanton, CA (US)

(21) Appl. No.: 15/081,686

(22) Filed: Mar. 25, 2016

(51) Int. Cl. H01L 31/0224; H01L 31/0216; H01L 31/068; H01L 23/544

(52) U.S. Cl. CPC H01L 31/022441; H01L 23/544; H01L 31/02168; H01L 31/068; H01L 2223/54413

(57) ABSTRACT

The present disclosure provides improved approaches for marking and individual tracking of solar cells. These approaches can be used to identify key manufacturing process steps requiring optimization and/or significant factors extending solar cell lifetime. The approaches described herein for marking and individual tracking of solar cells avoid or greatly minimize any negative impact on solar cell performance while improving quality control of solar cells across multiple manufacturing steps and throughout the entire solar cell lifecycle. Embodiments described herein include a solar cell comprising a substrate having a front side and a back side. The substrate comprises at least one diffusion region of a first polarity. A first set of conductive conduits in the first set is electrically coupled to at least one active diffusion region of a first polarity. The solar cell further comprises a marking above an inactive region of the substrate. The marking can provide information about a particular cell which can be read or scanned during cell manufacturing and/or in the field during the operational life of the cell.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-type doped and n-type doped regions in the substrate, thereby generating a voltage differential between the doped regions. The doped regions are connected to conductive regions on the solar cell to direct an electrical current from the cell to an external circuit coupled thereto.

In solar cell manufacturing, a large number of wafers or substrates having small dimensions are produced which can make precise quality control during solar cell production difficult. Some quality control methods trace back properties of a group of wafers or modules which can be imprecise and provide limited information. Individual tracking of solar cells can be used to identify key manufacturing process steps needing optimization and key factors extending solar cell lifetime. Accordingly, techniques for tracking solar cells are generally desirable. Some embodiments of the present disclosure allow for tracking or marking of solar cells and improve quality control of solar cells across multiple manufacturing steps and the entire solar cell lifecycle.

### BRIEF DESCRIPTION OF THE DRAWINGS

The following drawings illustrate by way of example and not limitation. For the sake of brevity and clarity, every feature of a given structure is not always labeled in every figure in which that structure appears. Identical reference numbers do not necessarily indicate an identical structure. Rather, the same reference number may be used to indicate a similar feature or a feature with similar functionality, as may non-identical reference numbers. The figures are not drawn to scale.

FIG. 1 depicts a perspective view of a solar cell, according to an embodiment;

FIG. 2 depicts a cross-sectional view of a solar cell, according to an embodiment;

FIG. 3 depicts a back side of a solar cell, according to an embodiment;

FIG. 4A and FIG. 4B depict cross-sectional views of a solar cell, according to an embodiment;

FIG. 5 depicts a portion of a solar cell and a corresponding quantum efficiency (QE) map, according to an embodiment;

FIG. 6A and FIG. 6B depict a magnified view of a negative back side edge of a solar cell, according to an embodiment;

FIG. 7A depicts a top down view of a string of shingled solar cells, according to an embodiment;

FIG. 7B depicts a cross-sectional view of a solar cell, according to an embodiment;

FIG. 8A and FIG. 8B exhibit optical images of a solar cell marking, according to an embodiment;

FIG. 9 depicts a solar cell fabrication method, according to an embodiment;

FIG. 10 shows a depth profile for an indentation of a solar cell marking according to an embodiment.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Certain terminology may be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “axial”, and “lateral” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

Terminology—The following paragraphs provide definitions and/or context for terms found in this disclosure (including the appended claims):

This specification includes references to “one embodiment” or “an embodiment.” The appearances of the phrases “in one embodiment” or “in an embodiment” do not necessarily refer to the same embodiment. Particular features, structures, or characteristics can be combined in any suitable manner consistent with this disclosure.

This term “comprising” is open-ended. As used in the appended claims, this term does not foreclose additional structure or steps.

Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

As used herein, the terms “first,” “second,” etc. are used as labels for nouns that they precede, and do not imply any type of ordering (e.g., spatial, temporal, logical, etc.). For example, reference to a “first” encapsulant layer does not necessarily imply that this encapsulant layer is the first encapsulant layer in a sequence; instead the term “first” is used to differentiate this encapsulant from another encapsulant (e.g., a “second” encapsulant).

The terms “a” and “an” are defined as one or more unless this disclosure explicitly requires otherwise.

The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

As used herein, “inhibit” is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

As used herein, the term “substantially” is defined as largely but not necessarily wholly what is specified (and includes what is specified; e.g., substantially 90 degrees includes 90 degrees and substantially parallel includes parallel), as understood by a person of ordinary skill in the art. In any disclosed embodiment, the terms “substantially,” “approximately,” and “about” may be substituted with “within [a percentage] of” what is specified, where the percentage includes 0.1, 1, 5, and 10 percent.

As used herein, “regions” can be used to describe discrete areas, volumes, divisions or locations of an object or material having definable characteristics but not always fixed boundaries.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present invention. The feature or features of one embodiment can be applied to other embodiments, even though not described or illustrated, unless expressly prohibited by this disclosure or the nature of the embodiments.

Some embodiments of the present disclosure allow for marking and individual tracking of solar cells which can be used, for example, to identify key manufacturing process steps requiring optimization and/or significant factors extending solar cell lifetime. Tracking solar cells or semiconductor wafers throughout a solar cell manufacturing process enables improved process control, as slight variations in processing conditions could be directly correlated to cell performance. Additionally, embodiments of the present disclosure facilitate optimization of solar cell manufacturing processes which can lead to improvements in cell efficiency. We also disclose herein a mechanism for fast and precise diagnosis of issues encountered during solar cell manufacturing processes and related quarantining of faulty cells. Some embodiments allow for improved reliability tracking over the lifetime of a solar cell, as failures during operation or in the field can be correlated with processing conditions. Some embodiments disclosed herein can curtail counterfeiting in addition to improving quality control of solar cells across multiple manufacturing steps and throughout the entire solar cell lifecycle. The approaches described herein for marking and individual tracking of solar cells avoid or greatly minimize any negative impact on solar cell performance.

Disclosed herein are solar cells. Although many of the examples described herein are back contact solar cells, the techniques and structures apply equally to other (e.g., front contact) solar cells as well. Moreover, although much of the disclosure is described in terms of solar cells for ease of understanding, the disclosed techniques and structures apply equally to other semiconductor structures (e.g., silicon wafers, or large area light emitting diodes, or substrates generally).

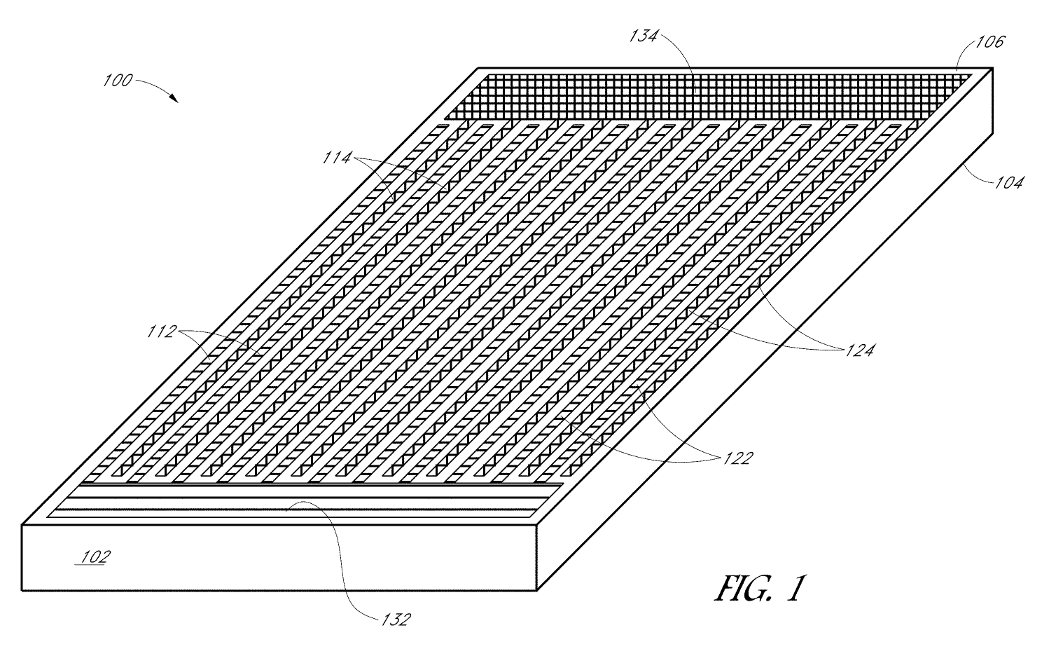

According to one embodiment depicted in FIG. 1, a solar cell 100 comprises a solar cell substrate or semiconductor wafer 102 having a front side 104 and a back side 106. The front side 104 can have a light-receiving surface facing the sun during normal operation to collect solar radiation. The solar cell substrate 102 may comprise a monocrystalline silicon wafer. As another example, the solar cell substrate 102 comprises an n-type silicon wafer. In other embodiments, the solar cell substrate comprises a p-type monocrystalline or p-type multi-crystalline silicon wafer.

In one embodiment, the solar cell is a back-contact solar cell such as depicted in FIG. 1. The solar cell 100 comprises a plurality of active diffusion regions of a first type or polarity 112 for collecting majority charge carriers and a plurality of active diffusion regions of a second type or polarity 114 for collecting minority charge carriers. Majority and minority charge carriers can be produced in the semiconductor substrate 102 upon receiving sunlight from the front side 104. In one embodiment, the plurality of active diffusion regions of the first and second polarity 112/114 are a plurality of alternating n-type and p-type doped semiconductor regions disposed in or above the back surface 106 of the substrate 102. The p-type and n-type diffusion regions can be formed in the solar cell substrate 102 or in another layer (e.g., polysilicon) formed on the solar cell substrate 102. In one exemplary embodiment described in further detail below, majority and minority carriers are formed in an n-type silicon wafer 102 comprising at least one active n-type diffusion region 112 for receiving negative majority carriers (e.g. electrons) and at least one active p-type diffusion region 114 for receiving positive minority carriers (e.g. holes). In other embodiments however, majority and minority carriers can be formed in an p-type silicon wafer comprising at least one active p-type diffusion region for receiving positive majority carriers (e.g. holes) and at least one active n-type diffusion region for receiving negative minority carriers (e.g. electrons).

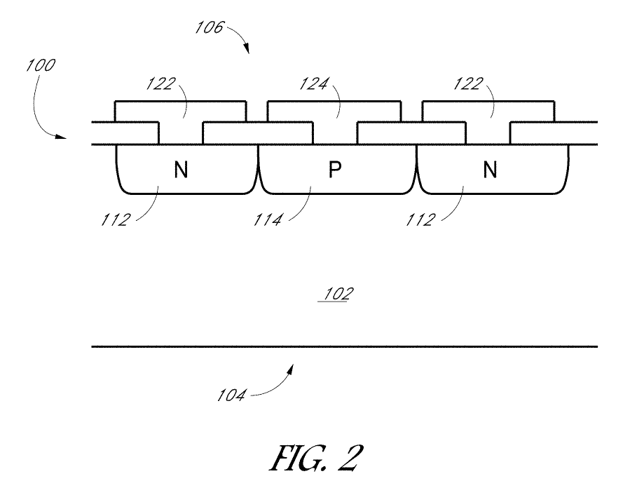

FIG. 2 depicts a cross sectional view of solar cell 100. A plurality of alternating n-type and p-type doped semiconductor regions 112/114 are disposed at the back surface 106 of the substrate 102. In this non-limiting example, the substrate 102 comprises an n-type silicon wafer. In an embodiment, conductive conduits are connected to the active diffusion regions to allow external circuits and devices to receive electrical power from the solar cell. As depicted in FIG. 2, a first and second set of conductive conduits or contact fingers 122/124 are disposed on the plurality of alternating n-type and p-type semiconductor regions 112/114. Each conductive conduit in the first set 122 is electrically coupled to an n-type active diffusion region 112 to collect majority charge carriers or electrons. Each conductive conduit in the second set 124 is electrically coupled to a p-type active diffusion region 114 to collect minority charge carriers or holes.

In one embodiment where substrate 102 comprises an n-type silicon wafer for example, an n-type doped region 112 and a p-type doped region 114 can form a base and an emitter, respectively, of the solar cell 100. The emitter collects minority charge carriers and the base collects majority charge carriers in the substrate 102. In embodiments where the substrate 102 comprises an n-type silicon wafer, electrons are the majority charge carriers collected in the doped region 112, while holes are the minority charge carriers and collected in the doped region 114. It should be appreciated, however, that in other embodiments, a neutral or p-type silicon substrate can be employed and for example, electrons could be the minority charge carriers and holes could be the majority charge carriers.

The first and second set of conductive conduits or contact fingers 122/124 are disposed on the plurality of alternating n-type and p-type semiconductor regions 112/114 as visible from the cross-sectional view of solar cell 100 depicted in FIG. 2. Referring again to FIG. 1, the first and second set of conductive conduits or contact fingers are generally indicated at 122 and 124, but it should be understood that the contact fingers 122/124 are substantially disposed above the plurality of alternating n-type and p-type semiconductor regions 112/114 given the top-down perspective shown in FIG. 1. In an embodiment, the first set of contact fingers 122 are interdigitated with the second set of contact fingers 124.

Conductive conduits or fingers can be formed of an electrically conductive material, for example an elemental metal or metal alloy (e.g. aluminum, copper, nickel, silver, gold). For ease of description, three contact fingers 122/124, each connected to three diffusion regions 112/114, are depicted in the illustration of FIG. 2 and twenty-two contact fingers 122/124, each connected to twenty-two diffusion regions 112/114, are depicted in the illustration of FIG. 1; however any desirable number of diffusion regions and conductive conduits in any desirable configuration can be provided.

As depicted in FIG. 1, the solar cell 100 further comprises a first inactive terminal region 132 on the back side 104 of the substrate 102. The first inactive terminal region 132 is electrically coupled to the first set of conductive conduits generally depicted at 122 which are in turn electrically coupled to diffusion regions 112. In some embodiments, the solar cell 100 further comprises a second terminal region 134 on the back side 104 of the substrate 102 opposite to the first inactive terminal region 132. The second terminal region 134 is electrically coupled to the second set of conductive conduits 124 which is in turn electrically coupled to diffusion regions 114. In one embodiment, the first inactive terminal region 132 and/or second terminal region 134 are located at or near an edge region of the solar cell 100 as depicted in FIG. 1, however terminal regions can be provided in any desirable location on or in the substrate 102 including side regions, edge regions, center regions or any combination thereof.

In some embodiments, solar cells can comprise pad-less terminals. For pad-less PV cells, active diffusion regions (e.g. p-type and n-type regions) and/or conductive fingers do not terminate at discrete contact pads but can be connected by bus bars or linear pads, for example. In some linear pad solar cell designs, conductive conduits or fingers can terminate at a peripheral edge of a semiconductor substrate and for example, with conductive conduits being connected by any desirable interconnect structure. In some embodiments, however, conductive conduits or fingers terminate at contact pads as described below.

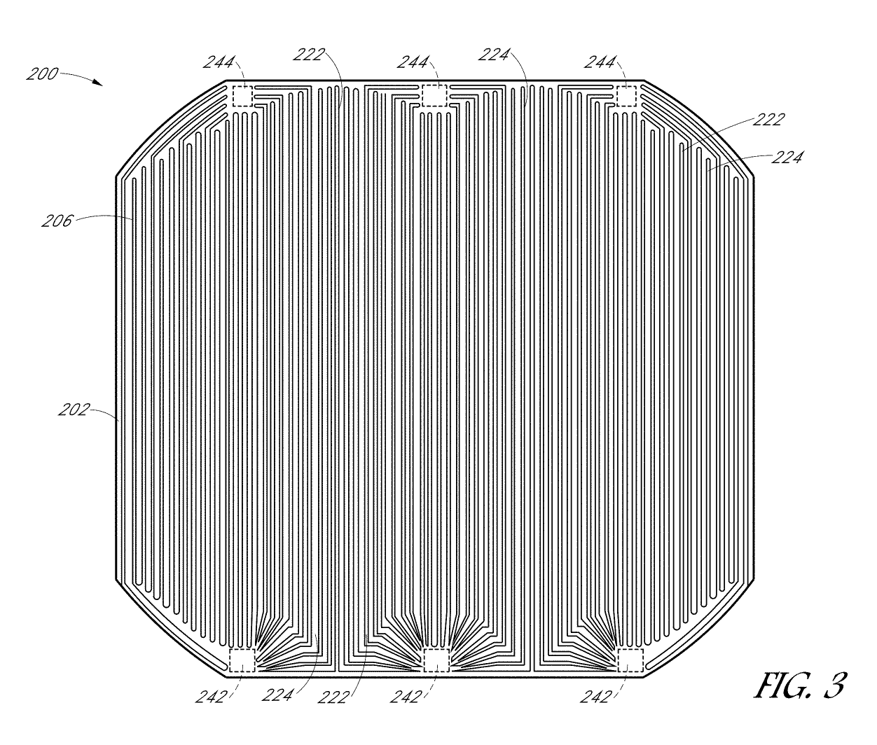

FIG. 1 and FIG. 2 illustrate a solar cell according to one embodiment. Unless otherwise designated, the components of FIG. 3-8 are similar, except that they have been incremented sequentially by 100.

FIG. 3 shows a back side 106 view of a solar cell 200 comprising a substrate 202 in accordance with an embodiment of the present disclosure. The solar cell 200 includes inactive terminal regions comprising a plurality of contact or contact pads 242/244 on opposing edges of the substrate 202. The inactive terminal regions comprising contact pads 242/244 have been generally marked with dashed lines. In FIG. 3, the contact pads 242 are on a negative edge portion of the solar cell 200, while the contact pads 244 are on the positive edge portion. The contact pads 242/244 provide a surface on which an interconnect lead electrically connecting solar cell 200 to another solar cell can be attached. Contact fingers 224 electrically connect p-type diffusion regions of substrate 202 to contact pads 244 on the positive edge portion. Contact fingers 222 electrically connect n-type diffusion regions of substrate 202 to contact pads 242 on the negative edge portion. In an embodiment, contact pads 242 only connect to contact fingers of a first polarity 222 and contact pads 244 only connect to contact fingers of a second polarity 224. Only a few of the metal contact fingers 222 and 244 have been labeled in the interest of clarity.

In an embodiment, contact fingers 222/224 are arranged such that their ends are oriented to point towards and surround the perimeter of the contact pads 242/244. The ends of contact fingers can bend at 90° angles (e.g. contact fingers 224 bending towards contact pads 244), at angles other than 90° (e.g. contact fingers 222 angled towards contact pads 242), a combination thereof or any other desirable configuration. In some embodiments, contact fingers can be substantially straight without any bends while terminating at terminal edge regions.

Contact or solder pads can be formed of an electrically conductive material, for example an elemental metal or metal alloy (e.g. aluminum, copper, nickel, silver, gold). In some embodiments, the contact or solder pad is substantially planar. In other embodiments, the contact or solder pad can comprise a coarse or roughened surface. In the illustration of FIG. 3, six contact pads 242/244 are depicted, however any desirable number of contact pads can be provided; for example in some embodiments a single contact pad is provided. The contact pads 242/244 are substantially square, however in other embodiments, contact pads can be provided in any desired shape. For example contact pads can be circular, oval, or square, stars, triangular, irregularly shaped, pointed, and so on. As another example with a circular contact pad, the ends of contact fingers can be configured to point to and surround the perimeter of the contact pad within a 180° radius, 90° radius, etc. Each contact finger preferably terminates on the perimeter of the solar pad. However, for optimization purposes, two contact fingers can end on the same contact finger, which in turn ends directly on the contact pad. In various embodiments, contact pads can be connected by bus bars so as to direct electrical current from the solar cell.

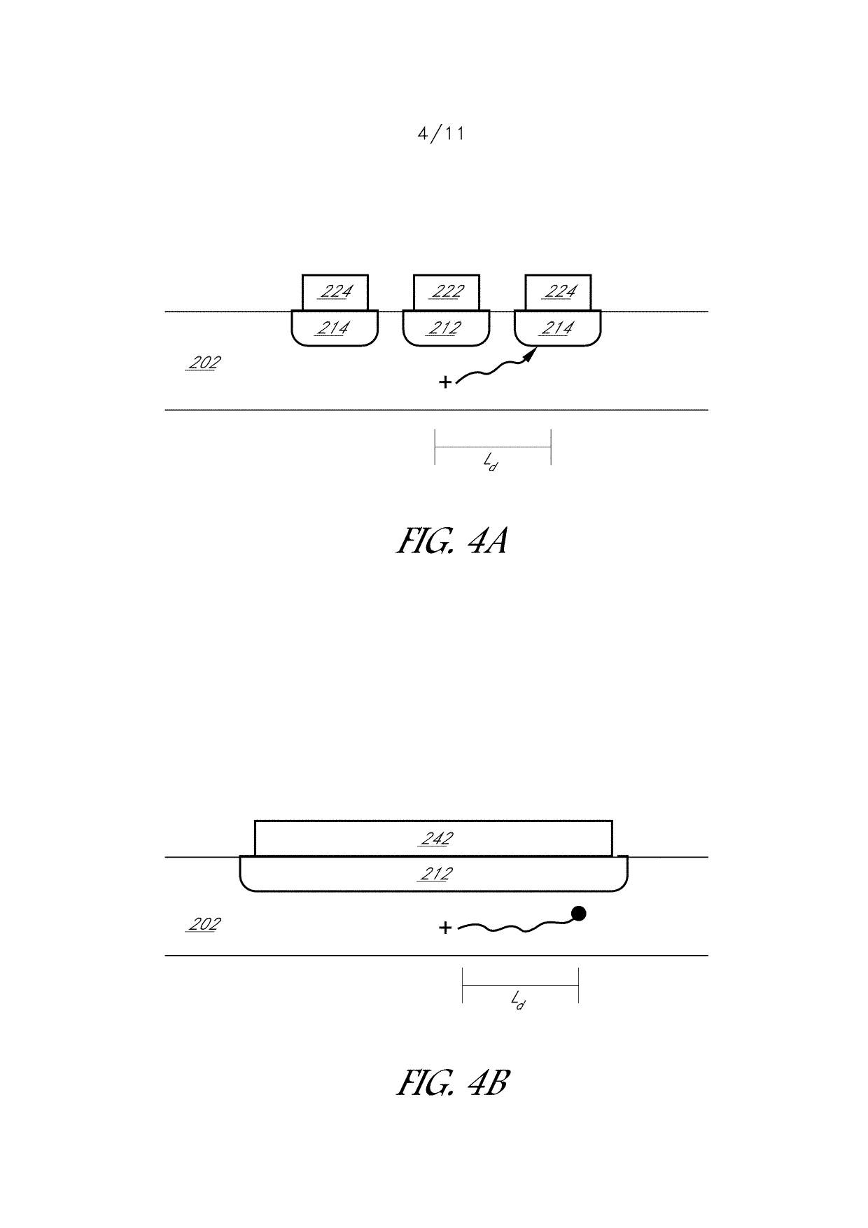

In one embodiment, the width of an inactive terminal region, for example a contact pad, is greater than the minority charge carrier diffusion length. In accordance with terminology and definitions understood by those skilled in the art, the carrier diffusion length L_{d} can be defined as the average distance a charge carrier can move from a point of generation in a substrate until it recombines. FIG. 4A and FIG. 4B depict cross-sectional views of solar cells according to various embodiments. In the example depicted in FIG. 4A, a minority charge carrier (e.g. hole) generated in the substrate 202 is capable of reaching diffusion region 214 for receiving positive minority carriers. As depicted in FIG. 4B however, minority charge carriers (e.g. hole) generated in the substrate 202 are negligibly collected because the minority carrier diffusion length L_{d} is less than the width of an inactive terminal region or contact pad 242.

In an embodiment, the collection of minority carriers limits the collection efficiency of a particular region of the cell. As used herein, the term “active” refers to a photovoltaically active region of a solar cell. In some embodiments, the charge carrier collection efficiency and/or minority charge carrier collection efficiency of an active region is greater than 50%. Conversely, the term “inactive” refers to a photovoltaically inactive region of a solar cell. For example, the charge collection efficiency of an inactive region can be less than 50%.

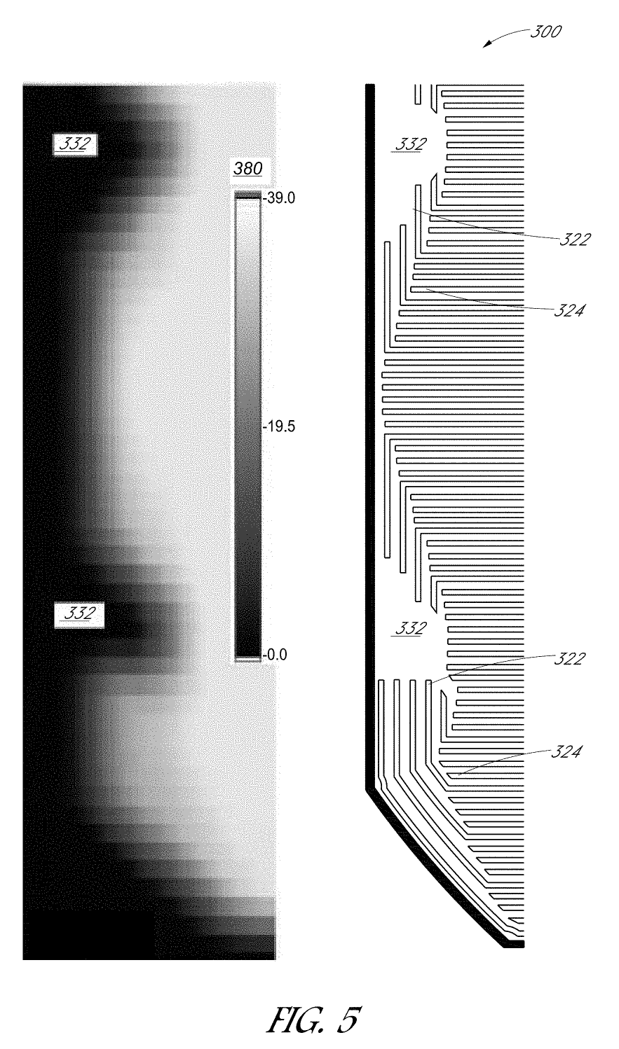

To provide an additional example of “active” and “inactive regions” of a solar cell, FIG. 5 exhibits results of a quantum efficiency (QE) scan for an edge of a solar cell. A QE scanner produces a map of the quantum efficiency of a solar cell which is the ratio of the number of charge carriers collected by the solar cell to the number of photons of a given energy incident on the solar cell. A back side terminal edge of a solar cell 300 is depicted at the right-hand side of FIG. 5 and a QE map of the same back side terminal edge of solar cell 300 is depicted on the left-hand side of FIG. 5. Regions of solar cell 300 characterized by high collection efficiency are indicated by a lighter color in the QE map and regions characterized by a lower collection efficiency are indicated by a darker color in the QE map. The scale 380 shows relative quantum or collection efficiency in arbitrary units. Solar cell 300 comprises a plurality of conductive conduits 322 for collection of majority charge carriers and a plurality of conductive conduits 324 to collect minority charge carriers. The solar cell 300 further comprises inactive terminal regions 332 which are electrically coupled to the plurality of conductive conduits 322 for collection of majority charge carriers. As depicted in FIG. 5, the inactive terminal regions 332 have a low collection efficiency such that they can be characterized as inactive regions of solar cell 300.

In an embodiment, inactive terminal regions comprise photovoltaically inactive regions having a charge carrier collection efficiency less than 50/o. Referring again to FIG. 1, inactive terminal regions 132/134 of solar cell 100 can have a minority charge carrier collection efficiency less than 50%. As another example, inactive edge portions of substrate 102 or 202 can have a minority charge carrier collection efficiency less than 50%. As yet another example, regions above or proximal to contact pads 242 at the negative edge portion of solar cell 200 can have a minority charge carrier collection efficiency less than 50%. In some embodiments, an inactive front side edge of an n-type silicon wafer located above negative contact pad has a charge carrier collection efficiency less than 50%.

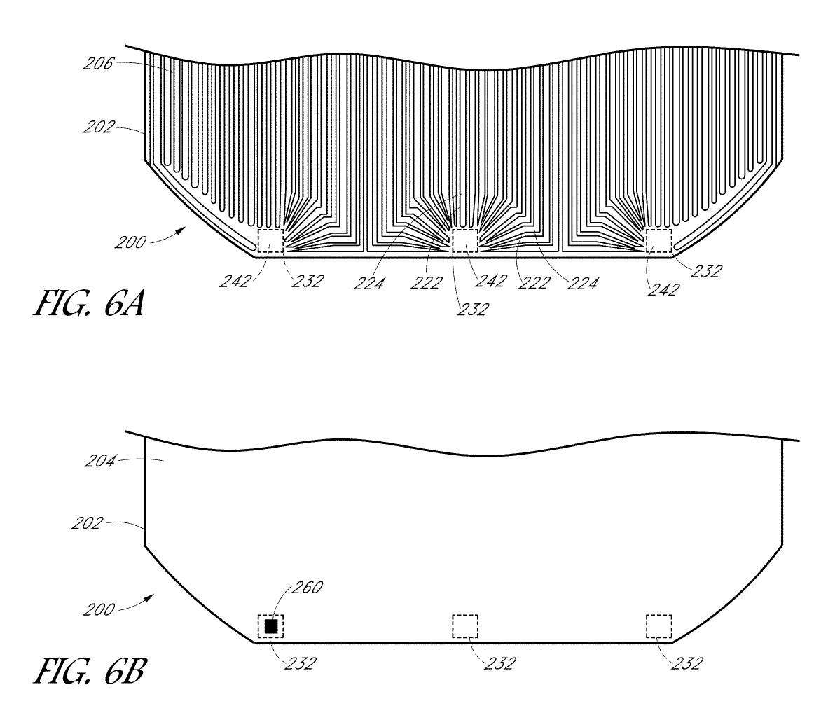

FIG. 6A and FIG. 6B show a magnified view of a negative edge portion of solar cell 200 according to one embodiment. The back side 206 of solar cell 200 is depicted in FIG. 6A and the front side 204 of solar cell 200 is depicted in FIG. 6B. The solar cell 200 includes inactive terminal regions 232 generally marked with dashed lines on both the front side 204 and back side 206 of solar cell 200. In an embodiment, the inactive terminal regions extend substantially through solar cell 200 from the front side 204 to the back side 206. As depicted in FIG. 6A, the negative terminal regions 232 comprise contact pads 242 on the back side 206 of solar cell 200.

As depicted in FIG. 6B, solar cell 200 comprises a marking 260 on the front side of solar cell 200. The marking 260 is located on or above an inactive terminal region 232. In one embodiment, the marking 260 is a machine-readable optical label that contains information about the solar cell 200. For example, the marking can store information relating to the solar cell manufacturing conditions and/or life cycle. The marking 260 can comprise a code employing a standardized encoding mode. For example, numeric, alphanumeric, binary, their derivatives and/or combinations thereof can be employed. In one embodiment, the marking 260 comprises a pattern of indentations etched into the front side 204 of the wafer or substrate 202. The pattern of indentations can be a dot matrix code or barcode. For example a Quick Response or “QR” code or Universal Product Code or “UPC” code can be used.

In several embodiments described herein, a marking is provided on or above an inactive region of a solar cell. In some embodiments, a marking is provided on the front side of a solar cell above a contact pad located on the back side of the solar cell, such as depicted in FIG. 6A-B. In other embodiments, a marking is provided opposite an inactive terminal region along an edge of a solar cell, for example the marking can be provided on a front side 104 edge opposite inactive terminal region 132 located at the back side 106 of solar cell 100 depicted in FIG. 1. In some embodiments, a marking or a portion of a marking can be provided on an inactive front side edge and/or inactive side edge of a solar cell or substrate. In an embodiment, provision of a marking on or above an inactive region of the solar cell can maintain solar cell efficiency and ensure the presence of the marking does not decrease solar cell efficiency.

In an embodiment, the marking is located on or above an inactive terminal region or contact pad coupled to conductive conduits and/or active diffusion regions of a first type or polarity for collecting majority charge carriers. Not to be bound by any particular theory, but the collection of minority carriers is limited by their diffusion length, and it is the collection of these carriers that determines the power output of the cell. The carrier diffusion length can be defined as the average distance a carrier can move from a point of generation in the substrate until it recombines. The collection efficiency can thereby be limited by the collection of minority carriers. The inventors have found that it can be advantageous for a marking to be located at a terminal region for conductive conduits that are electrically coupled to active diffusion regions for collecting majority carriers because the collection of minority charge carriers limits cell efficiency rather than the collection of majority charge carriers.

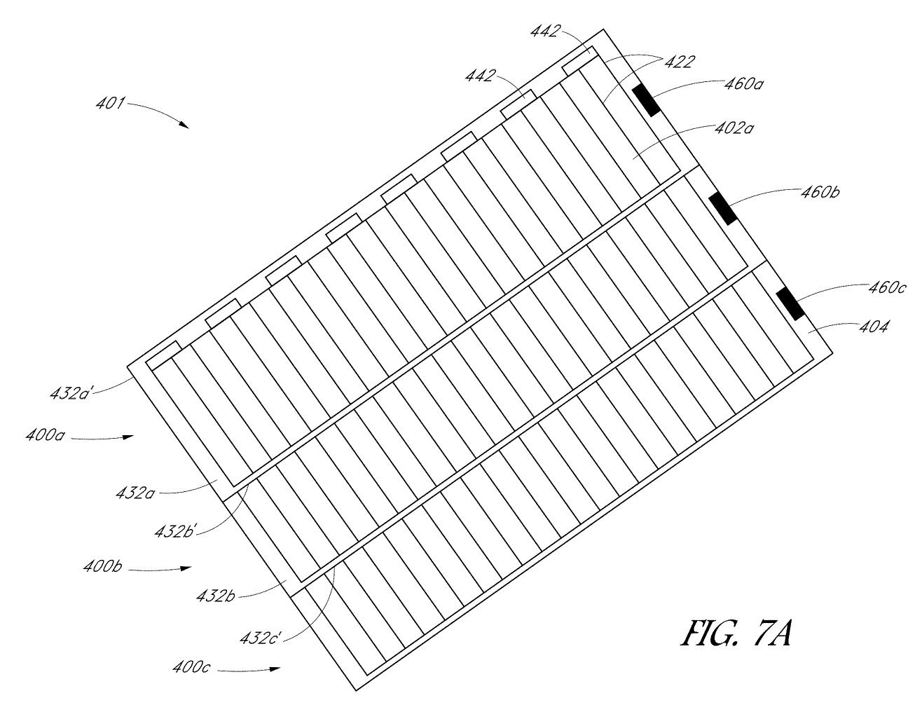

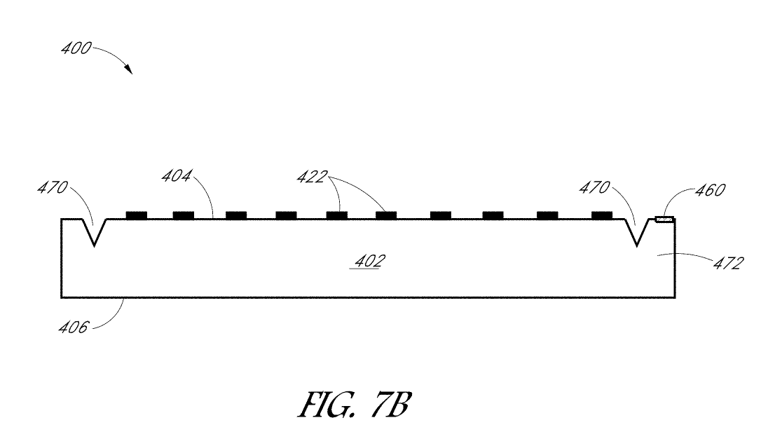

FIG. 7A depicts a front side 404 of a portion of a shingled solar cell string 401. The front side 404 can face the sun to collect solar radiation during normal operation. Solar cell string 401 comprises three front contact solar cells 400a-c connected in a shingled relationship such that a terminal edge region 432a of solar cell 400a is on top of a terminal edge region 432b′ of adjacent solar cell 400b and edge portion 432b of solar cell 400b is on top of edge portion 432c′ of adjacent solar cell 400c. As depicted, inactive terminal regions 432/432′ are located on the front side 404 of each solar cell 400a-c. Each solar cell 400a-c comprises contact pads 442, however only contact pads 442 of cell 400a are visible in FIG. 7A due to the shingled configuration. Each front contact solar cell 400a-c comprises a substrate 402 including n-type and p-type diffusion regions. On the front side 404 of solar cell string 401, n-type regions of each solar cell 400a-c can connect to negative conductive conduits, or fingers 422 which terminate into contact pads 442 of a negative terminal. On the back side of solar cell string 401 (not visible in FIG. 7A), p-type diffusion regions of each solar cell 400a-c can connect to contact pads of a positive terminal. Each solar cell 400a-c further comprises a marking 460a-c at an inactive front side edge of each solar cell 400a-c. Each marking 460a-c is located above an inactive edge region of solar cell 400a-c. In some embodiments, a marking can be provided at a terminal region which can become covered by an adjacent solar cell in a shingled relationship e.g. a marking can be at terminal region 432a′. As another example, a marking can be provided at a contact pad 442 and/or a bus bar extending across contact pads 442.

FIG. 7B depicts a cross-sectional view of a solar cell 400. In an embodiment, solar cell 400 is a front contact solar cell of a shingled solar cell string. Solar cell 400 has a front side 404 facing the sun to collect solar radiation during normal operation and a back side 406 opposite the front side 404. On the front side 404 of solar cell 400, diffusion regions in or above substrate 402 connect to conductive conduits 422 on the front side 404 of solar cell 400. In an embodiment, an edge region 472 of a front contact solar cell 400 is isolated to prevent shunting. For example, a laser scribe can produce a groove or trench 470 on the front side 404 of substrate 402, for example around the periphery of the solar cell 400. This isolated edge region 472 can therefore be inactive for charge collection. In such embodiments, a solar cell marking 460 can be provided in an edge isolation region 472, and will not affect the performance of the cell 400.

Disclosed herein is a solar cell e.g. a front-contact solar cell comprising a substrate or semiconductor wafer having a front side and a back side, the front side facing the sun during normal operation. In some embodiments, a plurality of front-contact solar cells can be configured into a shingled solar cell string. The substrate of the solar cell comprises at least one active diffusion region of a first polarity and/or at least one active diffusion region for collecting majority charge carriers. The substrate further comprises at least one active diffusion region for collecting minority carriers. The front-contact solar cell further comprises a first and second set of conductive conduits, wherein each conductive conduit in the first set is electrically coupled to at least one active diffusion region for collecting majority carriers and each conductive conduit in the second set is electrically coupled to at least one active diffusion region for collecting minority carriers. In an embodiment, the solar cell further comprises a first inactive region, for example an edge isolation region. In some embodiments, the cell comprises a trench on the front side of the substrate, wherein the trench separates active and inactive regions of the substrate. The solar cell further comprises a marking on the front side of the substrate, the marking being located on or above the first inactive region e.g. the inactive edge isolation region. In one embodiment, the width of the first inactive region is greater than a diffusion length of the minority charge carrier in the first inactive region. For example, the width of the first inactive region can be less than 2 mm. As another example, the width of the first inactive region can be less than 1 mm.

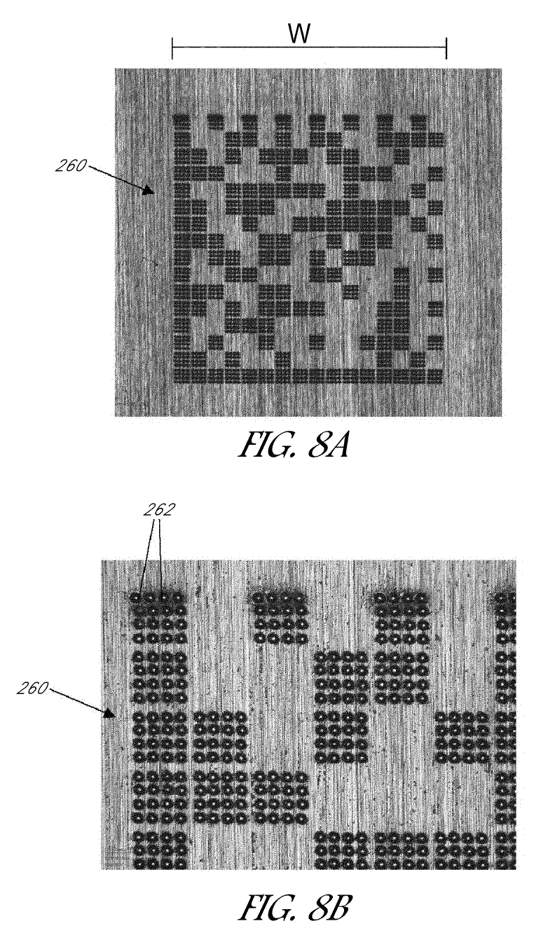

FIG. 8A exhibits optical images (obtained from optical profiler manufactured by Zeta instruments) of a solar cell marking 260 formed as a QR code. In an embodiment, the solar cell marking 260 comprises a plurality of indentations 262 arranged in a pattern. FIG. 8B shows a magnified view of solar cell marking 260 comprising indentations 262 configured in a pattern comprising a plurality of 4×4 matrices. Any desirable number of indentations can be arranged in any desirable configuration, matrix or array to facilitate individual marking of solar cells and their associated tracking.

In an embodiment, the size and shape of a solar cell marking can depend on the size of inactive terminal region above or on which the marking is provided, the amount of information the marking stores, the type and capability of an optical reader for reading the marking, or any combination thereof. As a non-limiting example, the marking can have a width W less than 2 mm and/or span across an area less than 3 mm² on the front side a solar cell. As another example, a marking with dimensions of 1.5 mm×1.5 mm can be used to code 24 numbers or 18 alpha-numeric characters.

In an embodiment a marking comprises indentations formed by laser ablation. For example, a fraction of the substrate material e.g. silicon is removed or ejected from the substrate upon laser irradiation which results in an indentation in the substrate. Further examples of laser ablation processes to form solar cell markings are described below.

Disclosed herein is a method for fabricating, marking and/or tracking a solar cell. Tracking marked wafers throughout the solar cell manufacturing process can improve process control, as slight variations in processing conditions can be directly correlated to performance. For example, each critical process step can have an associated marking or barcode reader. Solar cells can be scanned before and/or after a particular process step. Additionally solar cells which can be grouped into solar modules can be scanned in the field, for example over the operational lifetime of the solar module.

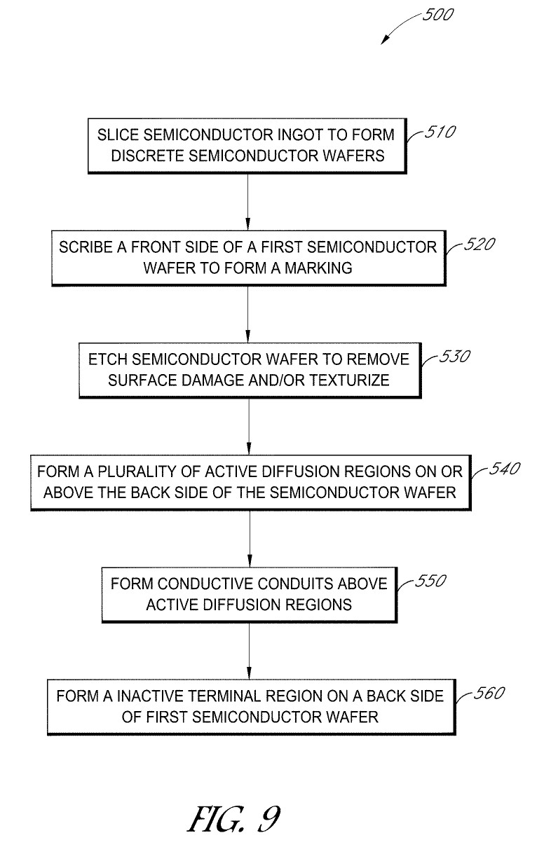

According to one embodiment, a method illustrated in flowchart 500 of FIG. 9 comprises a step 510 for slicing a semiconductor ingot e.g. silicon ingot to form a plurality of discrete semiconductor e.g. silicon wafers.

The method further comprises a scribing step 520 wherein a front side of a first substrate or wafer is scribed to form a marking at an inactive region of the solar cell. In an embodiment, the marking comprises at least one indentation formed by laser ablation.

The inventors have recognized that the indentation size, spacing and depth must be sufficient for the marking to robustly survive solar cell processing steps, but also as shallow as possible to minimize any impact on the structural integrity, efficiency, and/or appearance of the cell. Scribing with an infra-red (e.g. 1064 nm wavelength) laser can produce relatively deep indentations in the semiconductor wafer, but the semiconductor wafer can also be damaged resulting in a loss of solar cell efficiency. In various embodiments described herein, laser scribing with light in the visible or UV range can be desirable to produce a lower penetration depth into the substrate with less damage. The inventors have found that utilizing a laser having a wavelength less than 1064 nm, or in some embodiments less than 1000 nm (e.g. green laser having 532 nm wavelength) can allow for a desirable scribe producing shallow indentations. As a non-limiting example, the scribing process can produce indentations less than 8 μm. On subsequent solar cell processing steps, the size and/or depth of the marking can increase or decrease depending on the particular processing conditions.

In an embodiment, a solar cell manufacturing method further comprises an etching step 530 wherein a semiconductor wafer is contacted with an etching solution to texture and/or remove damage from surfaces of the semiconductor wafer. Depending on the concentration of the etchant and/or etching time, the depth and/or size of the marking indentations can increase or decrease.

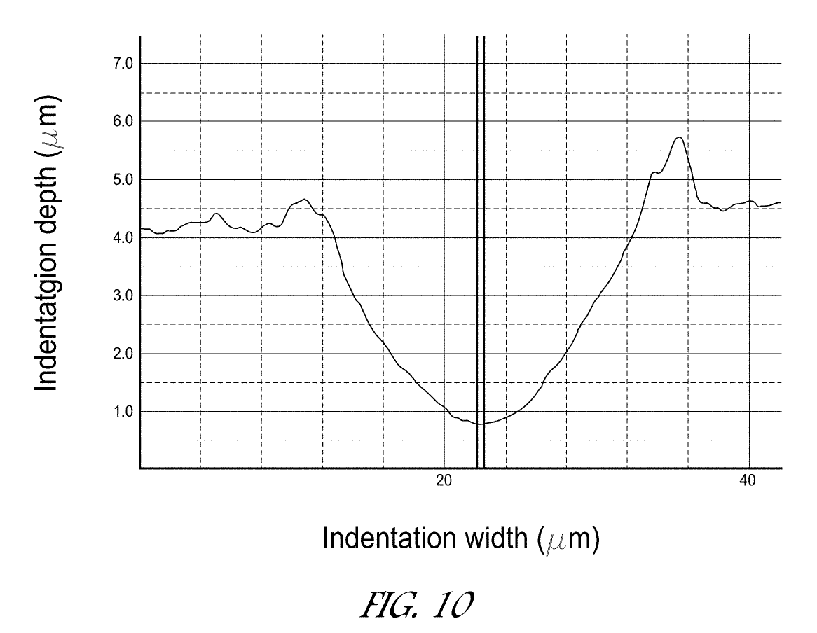

FIG. 10 shows a depth profile for an indentation of a solar cell marking according to an embodiment. In the non-limiting example of FIG. 10, the step of laser scribing produced an indentation having a depth of approximately 4 μm. In an embodiment, the marking is scribed to a depth at which the marking remains readable by an opto-electronic scanning device after the solar cell fabrication method is completed. The marking can be scribed to a depth as shallow as possible to minimize damage to the substrate, but still being readable by an opto-electronic scanning device after the solar cell fabrication method is completed. In one embodiment, the depth of the marking scribed is dependent on the subsequent steps in the solar cell manufacturing process.

Referring again to FIG. 9, the method further comprises a step 540 for forming active diffusion regions in or above the substrate and/or semiconductor wafer. For example, a plurality of alternating active diffusion regions of a first and second type or polarity can be formed on the backside of the first semiconductor wafer. The method can further comprise the step 550 for forming a first and second set of conductive conduits on the backside of the first semiconductor wafer. Each conductive conduit in the first set can be electrically coupled to one or more active diffusion regions of the first type and each conductive conduit in the second set can be electrically coupled to one or more active diffusion regions of the second type. In an embodiment, the second set of conductive conduits being interdigitated with the first set of conductive conduits.

The method can further comprise a step 560 for forming a first inactive terminal region on a back side of the first semiconductor wafer can be formed. In an embodiment, the first inactive terminal region is electrically coupled to the first set of conductive conduits. In one example, a contact pad can be formed as a contact surface onto which an external electrically conductive lead can be contacted e.g. soldered and/or connected by an electrically conductive adhesive. In an embodiment, the first inactive terminal region can be formed below the front side region comprising the marking.

In some embodiments, the solar cell fabrication method further comprises a step of forming an anti-reflective coating on the marking and the front side of the substrate or wafer. In an embodiment, the indentations can be textured and/or comprise an anti-reflective coating (ARC) which can facilitate optical reading of the code.

The above specification and examples provide a complete description of the structure and use of illustrative embodiments. Although certain embodiments have been described above with a certain degree of particularity, or with reference to one or more individual embodiments, those skilled in the art could make numerous alterations to the disclosed embodiments without departing from the scope of this invention. As such, the various illustrative embodiments of the methods and systems are not intended to be limited to the particular forms disclosed. Rather, they include all modifications and alternatives falling within the scope of the claims, and embodiments other than the one shown can include some or all of the features of the depicted embodiment. For example, elements can be omitted or combined as a unitary structure, and/or connections can be substituted. Further, where appropriate, aspects of any of the examples described above can be combined with aspects of any of the other examples described to form further examples having comparable or different properties and/or functions, and addressing the same or different problems. Similarly, it will be understood that the benefits and advantages described above can relate to one embodiment or can relate to several embodiments. For example, embodiments of the present methods and systems can be practiced and/or implemented using different structural configurations, materials, and/or control manufacturing steps. The claims are not intended to include, and should not be interpreted to include, means-plus- or step-plus-function limitations, unless such a limitation is explicitly recited in a given claim using the phrase(s) “means for” or “step for,” respectively.

1. A back-contact solar cell comprising:
an n-type silicon wafer having a front side facing the sun during normal operation to collect solar radiation and a back side opposite the front side; the n-type silicon wafer comprising at least one active n-type diffusion region at the back side;
a plurality of negative metal contact fingers on the back side of the n-type silicon wafer, each of the positive metal contact fingers being coupled to at least one active n-type diffusion region;
a first contact pad on a back side edge region of the n-type silicon wafer, the first contact pad providing a contact surface onto which an external lead can be connected to electrically connect to the negative metal contact fingers;
a marking on an inactive front side edge of the n-type silicon wafer located above the first contact pad, the marking comprising a pattern of indentations formed by laser ablation.

2. The back-contact solar cell of claim 1 further comprising:
a plurality of positive metal contact fingers on the back side of the n-type silicon wafer, each of the positive metal contact fingers being coupled to at least one active p-type diffusion region at the back side; the positive metal contact fingers being interdigitated with the negative metal contact fingers; and,
a second contact pad on a back side edge region of the n-type silicon wafer opposite to where the first contact pad is located, the second contact pad providing a contact surface onto which an external lead can be electrically connected to the negative metal contact fingers.

3. The back-contact solar cell according to claim 1, wherein the inactive front side edge of the n-type silicon wafer located above the first contact pad has a charge carrier collection efficiency less than 50%.

4. The back-contact solar cell according to claim 1 further comprising an anti-reflective coating on the marking and the front side of the n-type silicon wafer.

5. The back-contact solar cell according to claim 1, wherein the pattern of indentations is formed as a dot matrix code.

6. A solar cell comprising:
a substrate having a front side and a back side; the substrate comprising at least one active diffusion region of a first polarity;
a first set of conductive conduits on the back side of the solar cell, each conductive conduit in the first set being electrically coupled to at least one active diffusion region of the first polarity;
a first inactive terminal region on the back side of the semiconductor wafer, the first inactive terminal region being electrically coupled to the first set of conductive conduits; and,
a marking on the front side of the substrate, the marking being located above the first inactive terminal region.

7. The solar cell according to claim 6, further comprising:
a second set of conductive conduits on the back side of the substrate, each conductive conduit in the second set being electrically coupled to one or more diffusion regions of a second polarity opposite to the first polarity, the second set of conductive conduits being interdigitated with the first set of conductive conduits; and,
a second terminal region on the back side of the substrate opposite to where the first inactive terminal region is located, the second terminal region being electrically coupled to the second set of conductive conduits.

8. The solar cell according to claim 6, wherein the first inactive terminal region is located at an edge region of the substrate.

9. The solar cell according to claim 6, wherein the first inactive terminal region has a charge carrier collection efficiency less than 50%.

10. The solar cell according to claim 6, wherein the marking has a width less than 2 mm.

11. The solar cell according to claim 6, wherein the marking spans across an area less than 3 mm² of the front side of the substrate.

12. The solar cell according to claim 6, wherein the marking has a depth less than 8 μm.

13. The solar cell according to claim 6, wherein the marking comprises a pattern of indentations.

14. The solar cell according to claim 13, wherein the pattern of indentations form a dot matrix code.

15. The solar cell according to claim 6, wherein the marking comprises at least one indentation formed by laser ablation.

16. The solar cell according to claim 15, wherein the at least one indentation is formed by ablation of a surface portion of the front side by a laser having a wavelength below 1000 nm.

17. A solar cell comprising:
a semiconductor wafer having a front side and a back side; the semiconductor wafer comprising at least one active diffusion region for collecting minority charge carriers and at least one active diffusion region for collecting majority carriers;
a first set of conductive conduits, each conductive conduit in the first set being electrically coupled to at least one active diffusion region for collecting minority charge carriers;
a second set of conductive conduits, each conductive conduit in the second set being electrically coupled to the at least one active diffusion region for collecting majority charge carriers;
a first inactive region at an edge of the semiconductor wafer; and,
a marking on the front side of the semiconductor wafer, the marking being located above the first inactive region;
wherein a width of the first inactive region is greater than a diffusion length of the minority charge carrier in the first inactive region.

18. The solar cell according to claim 17, further comprising a trench on the front side of the semiconductor wafer, wherein the trench separates the first inactive edge region from active regions of the substrate.

19. The solar cell according to claim 17, wherein the width of the first inactive region is less than 2 mm.

20. The solar cell according to claim 17, wherein the first inactive region has a minority charge carrier collection efficiency less than 50%.
